(19) United States
(12) Patent Application Publication
(10) Pub. No.: US 2005/0110113 A1
(43) Pub. Date: May 26, 2005

(54) Anti-fuse structure employing metal silicide/doped polysilicon laminate

(75) Inventors: Chih-Ming Lin, Hsinchu City (TW); Kern-Hunt Ang, Hsin-Chu (TW); Chia-Chen Liu, Hsinchu City (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co., Ltd.

(21) Appl. No.: 10/721,578

(22) Filed: Nov. 24, 2003

(51) Int. Cl. H01L 29/00; H01L 21/326

(52) U.S. Cl. 257/530; 438/467; 438/600

(57) ABSTRACT

An anti-fuse structure and a method for forming the anti-fuse structure employ a substrate having formed therein a contact region. A metal silicide layer is formed over and electrically connected with the contact region. A first doped polysilicon layer is formed upon the metal silicide layer. An anti-fuse material layer is formed upon the first doped polysilicon layer. A second doped polysilicon layer is formed upon the anti-fuse material layer. The first doped polysilicon layer and the second doped polysilicon layer may be formed with the same or complementary dopant polarity, the latter providing an anti-fuse diode.

### BACKGROUND OF THE INVENTION

1. Field of the Invention

The invention relates generally to anti-fuse structures employed for fabricating microelectronic products. More particularly, the invention relates to anti-fuse structures with enhanced performance, as employed for fabricating microelectronic products.

2. Description of the Related Art

Anti-fuse structures are common in the microelectronic product fabrication art. In contrast to fuses, they provide programmable elements that allow for forming a conductive interconnect structure from a non-conductive interconnect structure. Typically, they are programmed employing an electrical programming voltage that is generally higher than an electrical circuit operating voltage. Anti-fuse structures find use in field programmable microelectronic memory and logic products where it is desirable for a user to program specific components into a specific electrical circuit to provide unique operating characteristics of the electrical circuit.

Although highly desirable in the microelectronic product fabrication art, anti-fuse structures are nonetheless not entirely without problems. In that regard, anti-fuse structures are often difficult to fabricate with enhanced performance. It is towards the foregoing object that the invention is directed.

### SUMMARY OF THE INVENTION

A first object of the invention is to provide an anti-fuse structure and a method for fabricating the anti-fuse structure.

A second object of the invention is to provide the anti-fuse structure and the method for fabricating the anti-fuse structure in accord with the first object of the invention, where the anti-fuse structure is fabricated with enhanced performance.

In accord with the objects of the invention, the invention provides an anti-fuse structure and a method for fabricating the anti-fuse structure.

In accord with the invention, the anti-fuse structure comprises a substrate having formed therein a contact region. The anti-fuse structure also comprises a metal silicide layer formed over and electrically connected with the contact region. The anti-fuse structure further comprises: (1) a first doped polysilicon layer formed upon the metal silicide layer; (2) an anti-fuse material layer formed upon the first doped polysilicon layer; and (3) a second doped polysilicon layer formed upon the anti-fuse material layer.

The anti-fuse structure of the invention may further comprises a conductor barrier layer formed interposed between the contact region and the metal silicide layer. Absent from the anti-fuse structure of the invention is a doped polysilicon layer formed interposed between the contact region and the metal silicide layer.

The anti-fuse structure of the invention contemplates a method for fabricating the anti-fuse structure of the invention.

The invention provides an anti-fuse structure with enhanced performance and a method for fabricating the anti-fuse structure.

The invention realizes the foregoing object within the context of an anti-fuse structure comprising a metal silicide layer having formed thereupon a first doped polysilicon layer in turn having formed thereupon an anti-fuse material layer finally in turn having formed thereupon a second doped polysilicon layer. Within the anti-fuse structure, the metal silicide layer provides for a lower resistance of the anti-fuse structure when fused, and thus enhanced performance of the anti-fuse structure.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3 and FIG. 4 show a series of schematic cross-sectional diagrams illustrating the results of progressive stages in forming an anti-fuse structure within a microelectronic product in accord with the invention.

FIG. 5 shows a schematic cross-sectional diagram of operation of the anti-fuse structure in accord with the invention.

### DESCRIPTION OF THE PREFERRED EMBODIMENT

The invention provides an anti-fuse structure with enhanced performance and a method for fabricating the anti-fuse structure.

The invention realizes the foregoing object within the context of an anti-fuse structure comprising a metal silicide layer having formed thereupon a first doped polysilicon layer in turn having formed thereupon an anti-fuse material layer finally in turn having formed thereupon a second doped polysilicon layer. Within the anti-fuse structure, the metal silicide layer provides for a lower resistance of the anti-fuse structure when fused, and thus enhanced performance of the anti-fuse structure.

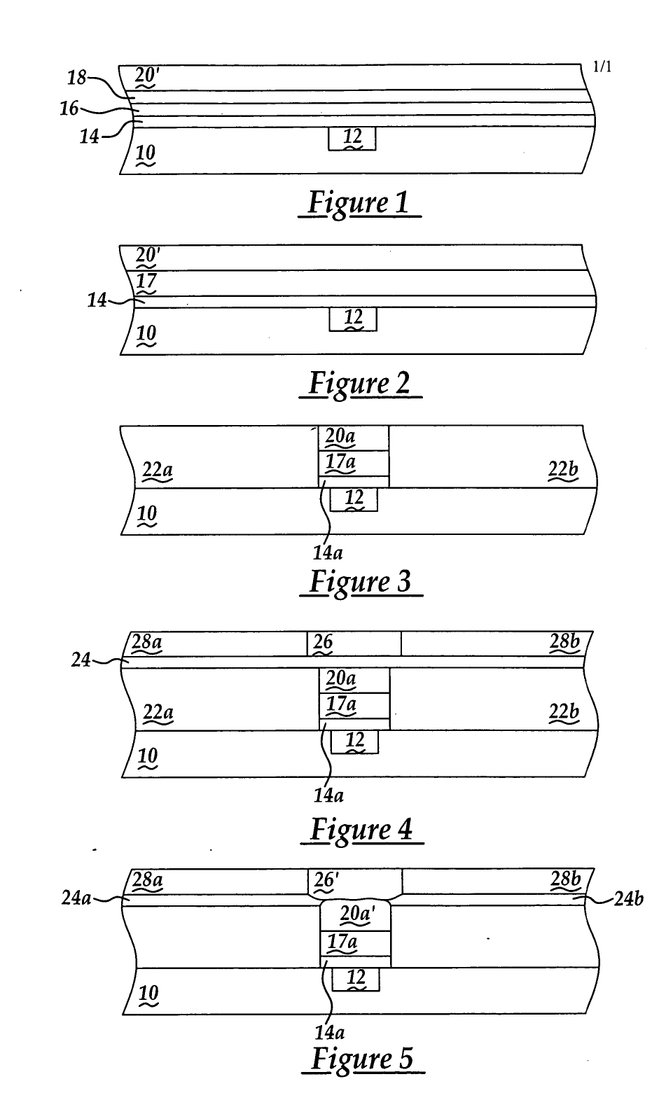

FIG. 1 to FIG. 4 show a series of schematic cross-sectional diagrams illustrating the results of progressive stages in forming an anti-fuse structure within a microelectronic product in accord with a preferred embodiment of the invention. FIG. 1 shows a schematic cross-sectional diagram of the microelectronic product at an early stage in its fabrication in accord with the preferred embodiment of the invention. Within the following figures, a substrate 10 is provided as a horizontal reference plane upon and over which additional layers or structures are formed, whether or not the substrate is eventually employed in a horizontal disposition.

FIG. 1 first shows the substrate 10 having formed therein a contact region 12.

The substrate 10 may be employed within a microelectronic product selected from the group including but not limited to integrated circuit products (including in particular semiconductor products), ceramic substrate products and optoelectronic products. Preferably, the substrate 10 comprises a semiconductor substrate having formed therein semiconductor devices whose selective interconnection may be effected employing an anti-fuse structure in accord with the invention.

The contact region 12 may be a conductor contact region (i.e., formed employing a conductor including but not limited to a metal, metal alloy, doped polysilicon (having a dopant concentration of from about 1E18 to about 1E22 dopant atoms per cubic centimeter) or metal silicide (doped polysilicon/metal silicide stack)) conductor. Alternatively, the contact region 12 may be a semiconductor contact region formed employing a semiconductor material including but not limited to less highly doped silicon, germanium and silicon-germanium alloy semiconductor materials (i.e., from about 1E14 to about 1E16 dopant atoms per cubic centimeter).

FIG. 1 also shows a series of blanket layers formed upon the substrate 10 having formed therein the contact region 12.

The series of blanket layers comprises: (1) a blanket conductor barrier layer 14 formed upon the substrate 10 having formed therein the contact region 12; (2) a blanket metal silicide forming metal layer 16 formed upon the blanket conductor barrier layer 14; (3) an optional blanket undoped polysilicon layer 18 formed upon the blanket metal silicide forming metal layer 16; and (4) a blanket first doped polysilicon layer 20 of a first polarity formed upon the optional blanket undoped silicon layer 18.

The blanket conductor barrier layer 14 may be formed of conductor barrier materials as are conventional in the microelectronic product fabrication art, including but not limited to nitrides of metal silicide forming metals such as but not limited to titanium, tungsten, cobalt, nickel, platinum, vanadium and molybdenum. The blanket conductor barrier layer 14 may be formed employing methods as are conventional in the art, to provide the blanket conductor barrier layer 14 of thickness from about 50 to about 500 angstroms. Preferably, the blanket conductor barrier layer 14 is formed of a titanium nitride conductor barrier material formed to a thickness of from about 100 to about 200 angstroms.

The blanket metal silicide forming metal layer 16 may, as noted above, be formed of a metal silicide forming metal employed for forming the blanket conductor barrier layer 14. Such metal silicide forming metals may be selected from the group including but not limited to titanium, tungsten, cobalt, nickel, platinum, vanadium and molybdenum. Typically, the blanket metal silicide forming metal layer 16 is formed to a thickness of from about 100 to about 500 angstroms. Preferably, the blanket metal silicide forming metal layer 16 is formed of titanium.

The optional blanket undoped silicon layer 18 may be formed of an amorphous undoped silicon material or a polycrystalline undoped silicon material. Typically, the optional blanket undoped silicon layer 18 is formed of a polycrystalline undoped silicon material formed to a thickness such as to provide for complete consumption of the blanket undoped silicon layer 18 when forming a metal silicide layer therefrom incident to thermal annealing with the blanket metal silicide forming metal layer 16. Typically the thickness will be from about 100 to about 500 angstroms.

Finally, the blanket first doped polysilicon layer 20 is formed of a doped polysilicon material as is otherwise conventional in the art, and formed with a first dopant polarity and a first dopant concentration. The first dopant polarity may be either an N polarity of a P polarity. The first dopant concentration may be either a −dopant concentration or a +dopant concentration. Preferably, the blanket first doped polysilicon layer 20 is formed with a P dopant polarity and a +dopant concentration (i.e., from about 1E20 to about 1E22 dopant atoms per cubic centimeter).

FIG. 2 first shows the results of thermally annealing the microelectronic product of FIG. 1 to form from the blanket metal silicide forming metal layer 16 and the blanket undoped silicon layer 16 (if present) a blanket metal silicide layer 17. Since the blanket metal silicide forming metal layer 16 is formed upon the blanket barrier layer 14, the thermal annealing proceeds such that a doped polysilicon layer is neither formed nor remains interposed between the blanket metal silicide layer 17 and the blanket barrier layer 14 or the contact region 12. Such thermal annealing also partially (and minimally) consumes the blanket first doped polysilicon layer 20 to form a partially consumed blanket first doped polysilicon layer 20′. When the blanket undoped silicon layer 18 is absent, the blanket metal silicide layer 17 is formed in conjunction with an enhanced consumption of the blanket first doped polysilicon layer 20. The use of the optional blanket undoped silicon layer 18 is desirable since the same provides for limited doping of the blanket metal silicide layer 17. The thermal annealing is undertaken at a temperature and for a time period appropriate for a metal silicide forming metal from which is formed the blanket metal silicide forming metal layer 16. Typically, the thermal annealing is undertaken at a temperature of from about 900 to about 1100 degrees centigrade and a rapid thermal annealing (i.e., thermal annealing temperature rise of from about 0.5 to about 2.0 seconds) time period of from about 0.5 to about 2.0 minutes, particularly when the blanket metal silicide forming metal layer 16 is formed of a titanium metal silicide forming metal.

FIG. 3 first shows the results of sequentially patterning the partially consumed blanket first doped polysilicon layer 20′, the blanket metal silicide layer 17 and the blanket barrier layer 14 to form a corresponding series of patterned layers comprising a patterned first doped polysilicon layer 20a aligned upon a patterned metal silicide layer 17a in turn aligned upon a patterned barrier layer 14a.

The foregoing patterning may be effected while employing etch methods as are conventional in the microelectronic product fabrication art, and as are appropriate to the materials from which are formed the partially consumed blanket first doped polysilicon layer 20′, the blanket metal silicide layer 17 and the blanket barrier layer 14. Although the etch methods may include wet chemical etch methods and dry plasma etch methods, anisotropic dry plasma etch methods are preferred.

FIG. 3 also shows the results of forming a pair of patterned planarized first dielectric layers 22a and 22b adjoining a pair of sidewalls of the stack comprising the patterned barrier layer 14a, the patterned metal silicide layer 17a and the patterned first doped polysilicon layer 20a.

The pair of patterned planarized first dielectric layers 22a and 22b may be formed employing methods and materials as are otherwise generally conventional in the microelectronic product fabrication art. Typically and preferably, the pair of patterned planarized first dielectric layers 22a and 22b is formed of a silicon oxide material formed employing a high density plasma chemical vapor deposition (HDP-CVD) method and planarized employing a chemical mechanical polish (CMP) planarizing method while employing the patterned first doped polysilicon layer 20a as a planarizing stop layer. Other methods and materials may also be employed.

FIG. 4 first shows a blanket anti-fuse material layer 24 formed upon the microelectronic product of FIG. 3, including the pair of patterned planarized first dielectric layers 22a and 22b and patterned first doped polysilicon layer 20a.

The blanket anti-fuse material layer may be formed of anti-fuse materials as are conventional in the microelectronic product fabrication art. Such anti-fuse materials may include, but are not limited to amorphous silicon or amorphous carbon anti-fuse materials, as well as more conventional dielectric anti-fuse materials, such as but not limited to silicon oxide, silicon nitride and silicon ox nitride dielectric anti-fuse materials. Preferably, the blanket anti-fuse material layer 24 is formed at least in part of a silicon oxide anti-fuse material, formed to a thickness of from about 10 to about 50 angstroms.

FIG. 4 also shows a patterned second doped polysilicon layer 26 formed upon the blanket anti-fuse material layer 24 and nominally centered above the patterned first doped polysilicon layer 20a. Analogously with the patterned first doped polysilicon layer 20a, the patterned second doped polysilicon layer 26 may also be formed of either dopant polarity (i.e., N or P) or either dopant concentration (i.e., − or +). The present invention provides particular value, however, under circumstances where the patterned second doped polysilicon layer 26 is formed of an N polarity and a −dopant concentration (i.e., from about 1E15 to about 1E17 dopant atoms per cubic centimeter) under circumstances where the patterned first doped polysilicon layer 24a is formed of a P+ polarity (or an analogous bilateral complementary dopant polarity and concentration ordering). Under such circumstances, an anti-fuse structure of the invention when fused provides a diode conductor structure rather than a pure conductor structure.

FIG. 5 shows a schematic cross-sectional diagram illustrating operation of the anti-fuse structure of FIG. 4.

As is illustrated in FIG. 5, incident to use of a proper programming voltage and programming current, the patterned first doped polysilicon layer 20a and the patterned second doped polysilicon layer 26 fuse to form a fused patterned first doped polysilicon layer 20a′ and a fused patterned second doped polysilicon layer 26′, while simultaneously forming a pair of patterned anti-fuse material layers 24a and 24b from the blanket anti-fuse material layer 24. In accord with the above disclosure, when each of the patterned first doped polysilicon layer 20a and the patterned second doped polysilicon layer 26 is of the same dopant polarity, the anti-fuse structure of FIG. 4 is fused to form a fused conductor interconnect structure. In contrast, when each of the patterned first doped polysilicon layer 20a and the patterned second doped polysilicon layer 26 is formed of opposite dopant polarity, the anti-fuse structure of FIG. 4 is fused to form an anti-fuse diode structure.

The invention provides an anti-fuse structure with enhanced performance. The invention realizes the foregoing object by employing a metal silicide layer within the anti-fuse structure, and by forming upon, and not beneath, the metal silicide layer a doped polysilicon layer. The metal silicide layer with the doped polysilicon layer formed thereupon but not therebeneath provides decreased anti-fuse electrical resistance when fused. The anti-fuse structure may also be formed employing a simple manufacturing process with a minimal number of doped polysilicon layers. The minimal number of doped polysilicon layers provides that the anti-fuse structure may further be fabricated employing simplified etch methods and chemical mechanical polish planarization methods when forming the anti-fuse structure.

The preferred embodiment of the invention is illustrative of the invention rather than limiting of the invention. Revisions and modifications may be made to materials, structures and dimensions in accord with the preferred embodiment of the invention while still providing an embodiment in accord with the invention, further in accord with the accompanying claims.

1. An anti-fuse structure comprising:
a substrate having formed therein a contact region;
a metal silicide layer formed over and electrically connected with the contact region;
a first doped polysilicon layer formed upon the metal silicide layer;
an anti-fuse material layer formed upon the first doped polysilicon layer; and
a second doped polysilicon layer formed upon the anti-fuse material layer.

2. The anti-fuse structure of claim 1 wherein the metal silicide layer is formed from a metal selected from the group consisting of titanium, tungsten, cobalt, nickel, platinum, vanadium and molybdenum metals.

3. The anti-fuse structure of claim 1 wherein the anti-fuse material layer is formed from an anti-fuse material selected from the group consisting of amorphous silicon materials, amorphous carbon materials and dielectric materials.

4. The anti-fuse structure of claim 1 wherein a doped polysilicon layer is not formed interposed between the contact region and the metal silicide layer.

5. The anti-fuse structure of claim 1 further comprising a barrier layer formed interposed between the contact region and the metal silicide layer and contacting the metal silicide layer.

6. An anti-fuse structure comprising:
a substrate having formed therein a contact region;
a metal silicide layer formed over and electrically connected with the contact region;
a first doped polysilicon layer of a first polarity formed upon the metal silicide layer;
an anti-fuse material layer formed upon the first doped polysilicon layer; and
a second doped polysilicon layer of a second polarity opposite the first polarity formed upon the anti-fuse material layer.

7. The anti-fuse structure of claim 6 wherein the metal silicide layer is formed from a metal selected from the group consisting of titanium, tungsten, cobalt, nickel, platinum, vanadium and molybdenum metals.

8. The anti-fuse structure of claim 6 wherein the anti-fuse material layer is formed from an anti-fuse material selected from the group consisting of amorphous silicon materials, amorphous carbon materials and dielectric materials.

9. The anti-fuse structure of claim 6 wherein a doped polysilicon layer is not formed interposed between the contact region and the metal silicide layer.

10. The anti-fuse structure of claim 6 further comprising a barrier layer formed interposed between the contact region and the metal silicide layer and contacting the metal silicide layer.

11. A method for forming an anti-fuse structure comprising:
providing a substrate having formed therein a contact region;
forming a metal silicide layer over and electrically connected with the contact region;
forming a first doped polysilicon layer upon the metal silicide layer;
forming an anti-fuse material layer upon the first doped polysilicon layer; and
forming a second doped polysilicon layer upon the anti-fuse material layer.

12. The method of claim 11 wherein the metal silicide layer is formed from a metal selected from the group consisting of titanium, tungsten, cobalt, nickel, platinum, vanadium and molybdenum metals.

13. The method of claim 11 wherein the anti-fuse material layer is formed from an anti-fuse material selected from the group consisting of amorphous silicon materials, amorphous carbon materials and dielectric materials.

14. The method of claim 11 wherein a doped polysilicon layer is not formed interposed between the contact region and the metal silicide layer.

15. The method of claim 11 further comprising forming a barrier layer interposed between the contact region and the metal silicide layer and contacting the metal silicide layer.

16. A method for forming an anti-fuse structure comprising:
providing a substrate having formed therein a contact region;
forming a metal silicide layer over and electrically connected with the contact region;
forming a first doped polysilicon layer of a first polarity upon the metal silicide layer;
forming an anti-fuse material layer upon the first doped polysilicon layer; and
forming a second doped polysilicon layer of a second polarity opposite the first polarity upon the anti-fuse material layer.

17. The method of claim 16 wherein the metal silicide layer is formed from a metal selected from the group consisting of titanium, tungsten, cobalt, nickel, platinum, vanadium and molybdenum metals.

18. The method of claim 16 wherein the anti-fuse material layer is formed from an anti-fuse material selected from the group consisting of amorphous silicon materials, amorphous carbon materials and dielectric materials.

19. The method of claim 16 wherein a doped polysilicon layer is not formed interposed between the contact region and the metal silicide layer.

20. The method of claim 16 further comprising forming a barrier layer interposed between the contact region and the metal silicide layer and contacting the metal silicide layer.
